(19) United States
(12) Patent Application Publication
(10) Pub. No.: US 2002/0116661 A1
(43) Pub. Date: Aug. 22, 2002

(54) Method and system for reporting events stored in non-volatile memory within an electronic device

(76) Inventors: Bill Thomas, Carmichael, CA (US); Rajiv Kumar Grover, Folsom, CA (US)

Correspondence Address: HEWLETT-PACKARD COMPANY, Intellectual Property Administration, P.O. Box 272400, Fort Collins, CO, 80527-2400, US

(21) Appl. No.: 09/730,653

(22) Filed: Dec. 5, 2000

(51) Int. Cl. H04L 1/22; H04B 1/74; H03K 19/003; H05K 10/00; H02H 3/05

(52) U.S. Cl. 714/17

(57) ABSTRACT

Method and system for reporting events stored in an event log of an electronic device to requesting remote computers. An event reporting mechanism within the electronic device inserts special watermark events into the event log in order to keep track of particular reporting threads. The reporting thread may be associated with a particular type of logged event and a particular requesting remote computer. Watermark events allow logged events to be reported without duplication and with minimal chance of omission. Implementation of the watermark-based event reporting technique does not require extensive changes to, or reformatting of, non-volatile memory-based events logs, and only minimal changes to the hardware circuitry or firmware that implements the event reporting mechanism within an electronic device.

### TECHNICAL FIELD

The present invention relates to retrieval of events from an event log stored in non-volatile memory within an electronic device and, in particular, to a method and system for retrieving events for reporting to remote computers interconnected with the electronic device.

### BACKGROUND OF THE INVENTION

With the advent of high-speed network communication media and increasing demands for shared access to large volumes of data by computer applications, it has become common to store data in data-storage peripheral devices, such as disk arrays, interconnected via a computer network medium to a number of different host computers and computer systems. Many other types of large peripheral devices, such as routers and highly-specialized servers, may also be interconnected via a network communications medium to multiple host computers. Although these high-end peripheral devices, or specialized network devices (“SNDs”), often provide limited console-type interfaces for administration purposes, it is common and far more efficient for a network or system administrator to access, monitor, and configure SNDs remotely from one or more remote computers interconnected via a network communications medium with the SNDs. To facilitate remote administration, an SND may implement an event log in non-volatile memory within the SND to store a sequential list of events detected by the SND for subsequent reporting by the SND via the network communications medium, or via a dedicated serial connection or other communications medium, to one or more remote computers that repeatedly collect events reported by the SND for automated analysis and for eventual display to a system manager or administrator.

FIG. 1 illustrates a typical event log. The event log 101 is a sequential list, or array, of entries, such as entry 102, that each contains a description of an event. In general, one field, or portion, of an entry, such as field 104 of entry 102, includes an indication of the type of event represented by the entry. Often, this type field contains an integer, each type of event represented by a unique integral value. In FIG. 1, the type fields of the entries contain a text representation of the type of event for clarity of illustration. In addition to a type field, entries generally contain some number of additional fields, in the case of entry 102, represented by the remaining portion 106 of the entry.

Because SNDs commonly lack convenient internal access to disk drives, or other types of random-access, non-volatile data storage components, event logs, such as the representative event log shown in FIG. 1, are commonly stored in non-volatile memory, such as an electrically erasable programmable read-only memory (“EEPROM”). The event log is constructed and maintained under control of firmware executed on a processor within the SND or, alternatively, under control of hardware circuits or a combination of hardware circuits and firmware. In comparison with random access memory (“RAM”) employed extensively in general-purpose computers, EEPROM is rather limited in functionality. Event log entries can be entered one-at-a-time into the event log, but the entries can be deleted only by deleting the entire contents of the EEPROM, including the event log in a single erase or flush operation. Once written to the EEPROM, an entry can be modified only by erasing the entire EEPROM and sequentially rebuilding the event log.

Limitations in the operations provided by EEPROM and related non-volatile memories, such as flash memory, correspondingly limit error reporting operations that may be undertaken by the hardware circuitry, firmware, or a combination of hardware and firmware that, along with the EEPROM, composes the event logging and reporting component within an SND. For example, if administration of the SND is shared between administration programs running on two different remote computers, it may be desirable, in some cases, for both remote computers to be able to retrieve a single copy of each event detected and logged by the SND. However, the firmware or logic circuits within the SND generally have no mechanism for storing indications of which events have been reported to a particular remote computer, nor even a mechanism for distinguishing already reported events from logged events that have not yet been reported. Currently, periodic access of event log entries from a remote computer generally entails receiving multiple reports of a single event. Currently, event reporting generally amounts to reporting of error events only. Other types of events are not remotely accessible. Alternatively, all types of events may be reported, resulting in reporting of many events unneeded by the application or human user receiving event reports via a remote computer. Commonly, a remote computer can only ask for, and receive, the list of events, or a portion of the list of events, currently contained within the event log within the SND.

Were a general-purpose computing environment available within the SND, many different types of sophisticated and flexible event reporting techniques could be employed by the SND, but, commonly, event logging and reporting is constrained by the characteristics of the non-volatile memory, such as EEPROM, and the difficulty of designing and manufacturing specialized circuitry and/or firmware for implementing event logging and reporting. Moreover, due to the legacy SNDs currently in use, and to profound compatibility issues involving many different levels of interfaces between event logging mechanisms within SNDs and the remote computers to which the event logs are reported, improved approaches to event logging and reporting that require extensive changes to currently employed event logging and reporting mechanisms may not be commercially viable.

For these reasons, designer and manufacturers of SNDs, and of remote SND administration software and interfaces, have recognized the need for improved event logging and reporting mechanisms within SNDs to provide a more flexible and robust event reporting interface for use by SND administration and monitoring applications that run on computers remote to SNDs without requiring extensive alteration and re-design of current event logging and reporting mechanisms.

### SUMMARY OF THE INVENTION

The present invention provides a method and system for logging and reporting events within specialized network devices (“SND”). As with current event logging and reporting systems within SNDs, the event logging and reporting systems of the present invention employs an event log implemented using non-volatile memory, such as an EEPROM or flash memory that provides a relatively limited number of basic memory operations. In order to provide a more robust and flexible event reporting interface, the method and system of the present invention employ a new type of entry, or event, referred to as a “watermark.” A watermark includes a relative offset from the watermark indicating a first entry in the event log for consideration in a subsequent event reporting operation related to the watermark. The watermark may contain additional fields that provide additional flexibilities in event reporting. For example, a watermark may include a second type field indicating a specific type of event to which the watermark is directed, so that a particular remote computer can request and receive events of a specified type. As another example, a watermark may include a remote computer identifier field that stores the identifier of a particular remote computer to which the watermark is directed, allowing each remote computer to retrieve events in multiple event retrieval operations from the SND independently from all other remote computers. The more robust and flexible event reporting made possible by use of watermarks can be achieved by relatively small changes to existing event logging and reporting systems within SNDs.

### BRIEF DESCRIPTION OF THE DRAWINGS

FIG. 1 illustrates a typical event log.

FIG. 2 illustrates an event log that includes watermarks.

### DETAILED DESCRIPTION OF THE INVENTION

The present invention provides a method and system for more robustly and flexibly reporting events from an event log stored within an SND. In one embodiment, the method and system of the present invention are incorporated within a fibre channel multiplexer interconnected with multiple host computers via a fibre channel and connected with a number of different small computer system interface (“SCSI”) busses that interconnect the fibre channel multiplexer device with a large number of data storage devices. In this embodiment, the event log is stored in sequential data storage locations within an EEPROM or flash memory, and the event log is populated, managed, and reported by a collection of firmware routines executing on a processor within the fibre channel multiplexer. However, the method of the present invention is applicable to a large number of different types of SNDs, and may be implemented in software, firmware, directly in logic circuits, or by a combination of software, firmware, and logic circuits. For the sake of clarity and brevity, current event reporting methods and the method of the present invention is described in a series of C++-like pseudocode class declarations and member function implementations.

A first set of C++-like pseudocode class declarations and member function implementations, below, implement generalized event log entries, or events:

| | |
|---|---|
| 1 | enum eventType {Error, Other, Watermark}; |
| 2 | |
| 3 | class time |
| 4 | { |
| 5 | }; |
| 6 | |
| 7 | class event |
| 8 | { |
| 9 | private: |

| | | |
|---|---|---|
| 10 | eventType | identifier; |
| 11 | time | timeOfEntry; |
| 12 | | |

| | |
|---|---|
| 13 | protected: |

| | | |
|---|---|---|
| 14 | eventType | evt1; |
| 15 | int | int1; |
| 16 | int | int2; |
| 17 | | |
| 18 | | |

| | |
|---|---|
| 19 | public: |

| | | |
|---|---|---|
| 20 | eventType | getIdentifier() {return identifier;} |
| 21 | void | setIdentifier(eventType e) {identifier = e;}; |
| 22 | time | getTime() {return timeOfEntry;}; |
| 23 | void | setTime(time t) {timeOfEntry = t;}; |
| 24 | event& | operator=(event&); |
| 25 | event(event&); | |
| 26 | event(); | |

| | |
|---|---|
| 27 | virtual ˜event(); |
| 28 | }; |
| 29 | |
| 30 | |

| | |
|---|---|
| 31 | class error : public event |
| 32 | { |
| 33 | public: |

| | | |
|---|---|---|
| 34 | int | getErrorType() {return int1;}; |
| 35 | void | setErrorType (int t) {int1 = t;}; |
| 36 | int | getComponentID() {return int2;}; |
| 37 | void | setComponentID (int c) {int2 = c;}; |
| 38 | error& | operator=(error& e); |
| 39 | error(error&); | |
| 40 | error(); | |

| | |
|---|---|
| 41 | }; |
| 42 | |
| 43 | class other : public event |
| 44 | { |
| 45 | public: |

| | |
|---|---|
| 46 | other(); |

| | |
|---|---|
| 47 | }; |
| 48 | |
| 49 | event& event::operator=(event& e) |
| 50 | { |

| | |
|---|---|
| 51 | error* er1; |
| 52 | error* er2; |
| 53 | watermark* wr1; |
| 54 | watermark* wr2; |
| 55 | |
| 56 | if (this != &e) |
| 57 | { |

| | |
|---|---|
| 58 | this->setIdentifier(e.getIdentifier()); |
| 59 | this->setTime(e.getTime()); |
| 60 | switch (e.getIdentifier()) |
| 61 | { |

| | |
|---|---|
| 62 | case Error: |

| | |
|---|---|
| 63 | er1 = reinterpret_cast<error*>(this); |
| 64 | er2 = reinterpret_cast<error*>(&e); |
| 65 | *er1 = *er2; |
| 66 | break; |

| | |
|---|---|
| 67 | case Other: |

| | |
|---|---|
| 68 | break; |

| | |
|---|---|
| 69 | case Watermark: |

| | |
|---|---|
| 70 | wr1 = reinterpret_cast<watermark*>(this); |
| 71 | wr2 = reinterpret_cast<watermark*>(&e); |
| 72 | *wr1 = *wr2; |
| 73 | break; |

| | |
|---|---|
| 74 | } |

| | |
|---|---|
| 75 | } |
| 76 | return *this; |

| | |
|---|---|
| 77 | } |
| 78 | |
| 79 | event::event(event& e) |
| 80 | { |

| | |
|---|---|
| 81 | error* er1; |
| 82 | error* er2; |
| 83 | watermark* wr1; |
| 84 | watermark* wr2; |
| 85 | |
| 86 | this->setIdentifier(e.getIdentifier()); |
| 87 | this->setTime(e.getTime()); |
| 88 | switch (e.getIdentifier()) |
| 89 | { |

| | |
|---|---|
| 90 | case Error: |

| | |
|---|---|
| 91 | er1 = reinterpret_cast<error*>(this); |
| 92 | er2 = reinterpret_cast<error*>(&e); |
| 93 | *er1 = *er2; |
| 94 | break; |

| | |
|---|---|
| 95 | case Other: |

| | |
|---|---|
| 96 | break; |

| | |
|---|---|
| 97 | case Watermark: |

| | |
|---|---|
| 98 | wr1 = reinterpret_cast<watermark*>(this); |
| 99 | wr2 = reinterpret_cast<watermark*>(&e); |
| 100 | *wr1 = *wr2; |
| 101 | break; |

| | |
|---|---|
| 102 | } |

| | |
|---|---|
| 103 | } |
| 104 | |
| 105 | |
| 106 | error& error::operator(error& p) |
| 107 | { |

| | |
|---|---|
| 108 | if (this != &p) |
| 109 | { |

| | |
|---|---|
| 110 | this->setIdentifier(Error); |
| 111 | this->setIdentifier(p.getIdentifier()); |
| 112 | this->setTime(p.getTime()); |
| 113 | this->setErrorType(p.getErrorType()); |
| 114 | this->setComponentID(p.getComponentID()); |

| | |
|---|---|
| 115 | } |
| 116 | return *this; |

| | |
|---|---|
| 117 | } |
| 118 | |
| 119 | error::error(error& p) |
| 120 | { |

| | |
|---|---|
| 121 | this->setIdentifier(Error); |
| 122 | this->setIdentifier(p.getIdentifier()) |
| 123 | this->setTime(p.getTime()); |
| 124 | this->setErrorType(p.getErrorType()); |
| 125 | this->setComponentID(p.getComponentID()); |

| | |
|---|---|
| 126 | } |
| 127 | |
| 128 | error::error() |
| 129 | { |

| | |
|---|---|
| 130 | this->setIdentifier(Error); |

| | |
|---|---|
| 131 | } |
| 132 | |
| 133 | |
| 134 | other::other() |
| 135 | { |

| | |
|---|---|
| 136 | this->setIdentifier(Other); |

| | |
|---|---|
| 137 | } |

The enumeration “eventType,” declared above on line 1, provides three types of event log entries, two of which are discussed immediately below: (1) “Error,” an error event that represents an error condition detected within an SND and stored within an event log; and (2) “Other,” any other type of event that may be entered into the event log. In general, current SND event reporting generally involves only error reporting. Only errors stored within an event log are extracted and reported to remote computers by an error reporting mechanism within the SND. Other types of events, such as events related to internal components, including power-on and power-off events, events related to network conditions, events related to updates of hardware and firmware internal components, and other types of events, are accessed directly from the console of the SND. One of the disadvantages of current event reporting techniques is that, commonly, a remote computer may access only error events or, alternatively, may receive the entire contents of an event log without the ability to select a type of event to retrieve.

The class “time,” declared above on lines 3-5, represents a time stamp, an instance of which is instantiated by the SND upon detection of an event and stored in the event log entry corresponding to the detected event. The details of this class are unnecessary for description of the present invention, and are therefore omitted.

The class “event,” declared above on lines 7-28, is the base class for events, or equivalently, in the current implementation, event log entries. The class “event” includes two private data members, declared above on lines 10-11: (1) “identifier,” a member that contains an eventType value indicating the type of event represented by an instance of the class “event;” and (2) “timeOfEntry,” a time stamp associated with the event represented by an instance of the class “event.” The class “event” additionally contains three protected data members that may be used for storing different types of information by derived classes that inherit the class “event” as a base class. The class “event” includes member functions that retrieve and store values for the identifier and time stamp, declared above on lines 20-23, an assignment operator and copy constructor, declared above on lines 24-25, and a constructor and destructor, declared above on lines 26-27. Note that member functions that retrieve a value from a data member have names prefixed with “get” and member functions that store values into data members have names with the prefix “set,” according to standard C++ naming conventions.

The derived class “error,” one type of event or event log entry, is declared above on lines 31-41. The class “error” contains additional member functions that allow retrieving and storing of an error type, an integer representation of the type of error represented by an instance of the class “error,” and that allow retrieving and storing of a component ID, an integer representation of the identity of an internal component associated with the error. The class “other,” declared above on lines 43-47, represents any other derived class that inherits the class “event” as a base class. Specific examples of other types of events are not needed to illustrate the present invention, and are therefore omitted.

For completeness, implementations of assignment operators and copy constructors for the classes “event” and “error,” as well as additional constructors, are provided above on lines 49-137. These constructor and operator member functions are straightforward, and are not discussed further.

Next, a pseudocode representation of the functionality provided by a non-volatile memory component, such as an EEPROM, is provided below:

| | |
|---|---|
| 1 | const int MEM_SIZE = 1000; |
| 2 | |
| 3 | class bareMemory |
| 4 | { |
| 5 | private: |

| | | |
|---|---|---|
| 6 | event* | mem; |
| 7 | int | next; |
| 8 | | |

| | |
|---|---|
| 9 | public: |

| | | |
|---|---|---|
| 10 | void | addEntry(event* nxtEvent); |
| 11 | bool | getEntry(int offset, event& evnt); |
| 12 | int | getNextOffset() {return next;}; |
| 13 | void | flush(); |
| 14 | bool | full() {return next == MEM_SIZE;}; |

| | |
|---|---|
| 15 | bareMemory(); |
| 16 | virtual ˜bareMemory(); |
| 17 | }; |
| 18 | |

| | | |
|---|---|---|
| 19 | void | bareMemory::addEntry(event* nxtEvent) |
| 20 | { | |

| | |
|---|---|
| 21 | if (full()) return; |
| 22 | else mem[next++] = *nxEvent; |

| 23 | } | |
|---|---|---|
| 24 | | |
| 25 | bool | bareMemory::getEntry(int offset, event& evnt) |
| 26 | { | |

| | |
|---|---|
| 27 | if (offset >= 0 && offset <next) |

| | |
|---|---|
| 28 | { |

| | |
|---|---|
| 29 | evnt = mem[offset]; |
| 30 | return true; |

| | |
|---|---|
| 31 | } |
| 32 | else return false; |

| 33 | } | |
|---|---|---|
| 34 | | |
| 35 | void | bareMemory::flush() |
| 36 | { | |

| | |
|---|---|
| 37 | next = 0; |

| | |
|---|---|
| 38 | } |
| 39 | |
| 40 | bareMemory::bareMemory() |
| 41 | { |

| | |
|---|---|
| 42 | next = 0; |
| 43 | mem = new event[MEM_SIZE]; |

| | |
|---|---|
| 44 | } |

The constant “MEM_SIZE,” declared above on line 1, is an arbitrary maximum size, in entries, of the memory component. The class “bareMemory,” declared above on lines 3-17, defines the operations provided by the memory component. These include: (1) “addEntry,” declared above on line 10, that adds an event supplied in a calling argument to the next open position in the memory component; (2) “getEntry,” declared above on line 10, that returns in a supplied event object “evnt” the contents of the event stored in the memory component at the offset with respect to the beginning of the event log supplied in argument “offset;” (3) “getNextOffset,” declared above on line 12, that returns the offset of the next available position within the memory component for storing an event; (4) “flush,” declared above on line 13, that erases the entire contents of the memory component, leaving the first entry as the next available entry into which an event may be stored; (5) “full,” declared above on line 14, that returns a Boolean value indicating whether or not the memory component is full; and (6) a constructor and destructor, declared above on lines 15-16. The class “bareMemory” includes two private data members, declared above on lines 6-7: (1) “mem,” a pointer to an array of entries, essentially the storage medium; and (2) “next,” a pointer to the next available entry within the array of events. Implementations of various member functions of the class “bareMemory” are provided on lines 19-44, above. Note that member function “getEntry,” implemented above on lines 25-33, returns an entry only if the supplied offset responds to a valid entry stored in the memory component, and returns a Boolean value indicating whether or not a valid entry occurs in the memory component at the supplied offset.

Next, a series of classes representing current and possible error event reporting methods are provided, to clearly illustrate various deficiencies overcome by the present invention:

| | |
|---|---|
| 1 | typedef event* eventBuffer; |
| 2 | |
| 3 | class getErrors1 |
| 4 | { |
| 5 | private: |

| | |
|---|---|
| 6 | bareMemory* mem; |

| | |
|---|---|
| 7 | public: |

| | |
|---|---|
| 8 | int getErrors(eventBuffer buf, int size); |
| 9 | getErrors1(bareMemory* m); |
| 10 | virtual ˜getErrors1(); |

| | |
|---|---|
| 11 | }; |
| 12 | |
| 13 | class getErrors2 |
| 14 | { |
| 15 | private: |

| | |
|---|---|
| 16 | bareMemory* mem; |

| | |
|---|---|
| 17 | public: |

| | |
|---|---|
| 18 | int getErrors(eventBuffer buf, int size, int & offset); |
| 19 | getErrors2(bareMemory* m); |
| 20 | virtual ˜getErrors2(); |
| 21 | |

| | |
|---|---|
| 22 | }; |
| 23 | |
| 24 | class getErrors3 |
| 25 | { |
| 26 | private: |

| | |
|---|---|
| 27 | bareMemory* mem; |

| | |
|---|---|
| 28 | public: |

| | |
|---|---|
| 29 | int getErrors(eventBuffer buf, int size); |
| 30 | getErrors3(bareMemory* m); |
| 31 | virtual ˜getErrors3(); |
| 32 | |

| | |
|---|---|
| 33 | }; |
| 34 | |
| 35 | class getErrors4 |
| 36 | { |
| 37 | private: |

| | |
|---|---|
| 38 | bareMemory* mem; |
| 39 | bool retrieved[MEM_SIZE]; |

| | |
|---|---|
| 40 | public: |

| | |
|---|---|
| 41 | int getErrors(eventBuffer buf, int size); |
| 42 | getErrors4(bareMemory* m); |
| 43 | virtual ˜getErrors4(); |

| | |
|---|---|
| 44 | }; |
| 45 | |
| 46 | int getErrors1::getErrors (eventBuffer buf, int size) |
| 47 | { |

| | |
|---|---|
| 48 | event e; |
| 49 | int i = 0; |
| 50 | int j = 0; |
| 51 | |
| 52 | while (mem->getEntry(i, e)) |
| 53 | { |

| | |
|---|---|
| 54 | if (e.getIdentifier() == Error) |
| 55 | { |

| | |
|---|---|
| 56 | j++; |
| 57 | *buf++ = e; |
| 58 | if (j == size) break; |

| | |
|---|---|
| 59 | } |
| 60 | i++; |

| | |
|---|---|
| 61 | } |
| 62 | return j; |

| | |
|---|---|
| 63 | } |
| 64 | |
| 65 | getErrors1::getErrors1(bareMemory* m) |
| 66 | { |

| | |
|---|---|
| 67 | mem = m; |

| | |
|---|---|
| 68 | } |
| 69 | |
| 70 | int getErrors2::getErrors(eventBuffer buf, int size, int & offset) |
| 71 | { |

| | |
|---|---|
| 72 | event e; |
| 73 | int i = offset; |
| 74 | int j = 0; |
| 75 | |
| 76 | while (mem->getEntry(i, e)) |
| 77 | { |

| | |
|---|---|
| 78 | if (e.getIdentifier() == Error) |
| 79 | { |

| | |
|---|---|
| 80 | j++; |
| 81 | *buf++ = e; |
| 82 | if (j == size) break; |

| | |
|---|---|
| 83 | } |
| 84 | i++; |

| | |
|---|---|
| 85 | } |
| 86 | offset = i; |
| 87 | return j; |

| | |
|---|---|
| 88 | } |
| 89 | |
| 90 | getErrors2::getErrors2(bareMemory* m) |
| 91 | { |

| | |
|---|---|
| 92 | mem = m; |

| | |
|---|---|
| 93 | } |
| 94 | |
| 95 | int getErrors3::getErrors(eventBuffer buf, int size) |
| 96 | { |

| | |
|---|---|
| 97 | event e[MEM_SIZE]; |
| 98 | int i = 0; |
| 99 | int k = 0; |
| 100 | int j = 0; |
| 101 | |
| 102 | while (mem->getEntry(i, e[k])) |
| 103 | { |

| | |
|---|---|
| 104 | if (e[k].getIdentifier() == Error) |
| 105 | { |

| | |
|---|---|
| 106 | if (j < size) |
| 107 | { |

| | |
|---|---|
| 108 | j++; |
| 109 | *buf++ = e[k]; |

| | |
|---|---|
| 110 | } |

| | |
|---|---|
| 111 | } |
| 112 | else k++; |
| 113 | i++; |

| | |
|---|---|
| 114 | } |
| 115 | mem->flush(); |
| 116 | for(i = 0; i < k; i++) |
| 117 | { |

| | |
|---|---|
| 118 | mem->addEntry(&(e[i])); |

| | |
|---|---|
| 119 | } |
| 120 | return j; |

| | |
|---|---|
| 121 | } |
| 122 | |
| 123 | getErrors3::getErrors3(bareMemory* m) |
| 124 | { |

| | |
|---|---|
| 125 | mem = m; |

| | |
|---|---|
| 126 | } |
| 127 | |
| 128 | int getErrors4::getErrors(eventBuffer buf, int size) |
| 129 | { |

| | |
|---|---|
| 130 | event e; |
| 131 | int i = 0; |
| 132 | int j = 0; |
| 133 | |
| 134 | while (mem->getEntry(i, e)) |
| 135 | { |

| | |
|---|---|
| 136 | if (e.getIdentifier() == Error && !retrieved[i]) |
| 137 | { |

| | |
|---|---|
| 138 | j++; |
| 139 | *buf++ = e; |
| 140 | retrieved[i] = true; |
| 141 | if (j == size) break; |

| | |
|---|---|
| 142 | } |
| 143 | i++; |

| | |
|---|---|
| 144 | } |
| 145 | return j; |

| | |
|---|---|
| 146 | } |
| 147 | |
| 148 | getErrors4::getErrors4(bareMemory* m) |
| 149 | { |

| | |
|---|---|
| 150 | mem = m; |
| 151 | for(int i = 0; i < MEM_SIZE; i++) |
| 152 | { |

| | |
|---|---|
| 153 | retrieved[i] = false; |

| | |
|---|---|
| 154 | } |

| | |
|---|---|
| 155 | } |

As discussed above, current event reporting is generally focused on reporting errors to remote computers, and therefore the various illustrative classes declared and implemented above have names beginning with the prefix “getErrors.” The classes “getErrors1,” “getErrors2,” “getErrors3,” and “getErrors4” are declared above on lines 3-44. Each of these classes provides a single operation, implemented as a public member function “getErrors.” All four classes contain a private data member “mem” that references a memory component, and class “getErrors4” additionally contains an array of Boolean values, “retrieved,” that indicates whether or not a corresponding entry stored in the memory component was previously reported.

An implementation of the member function “getErrors” for class “getErrors1” is provided above on lines 46-63. This implementation illustrates the most common approach to reporting errors from an event log within an SND. The routine is supplied a buffer, or pointer to an array of events, into which to place errors extracted from the event log, and is also supplied with an integer “size” that indicates the size of the buffer into which errors are to be placed. The member function “getErrors,” in the while-loop comprising lines 52-61, starts at the first entry of the memory component, or event log, and determines, on line 54, whether or not each valid entry is an error entry. Error entries are copied into the supplied buffer on line 57. If the supplied buffer is filled, as detected on line 58, then getErrors returns the size of the buffer on line 62. Otherwise, if the while-loop completes, and all event log entries have been considered, getErrors returns, on line 62, the number of errors copied to the buffer.

The error reporting technique illustrated by member function “getErrors” of class “getErrors1” is deficient in many ways. First, if multiple remote computers are accessing the SND for error reporting, each remote computer receives all detected errors. It is therefore difficult to partition error analysis and reporting between a number of remote computers, because, to do so, each remote computer must exchange information with all other remote computers in order to determine which errors have already been reported. Moreover, a remote computer may have to dedicate a relatively large error buffer within memory in the case that the SND has accumulated a large number of errors in its event log, because there is no way for the remote computer to request a logical subset of the errors currently stored within the event log. If the remote computer requests errors, then all errors within the event log, starting at the beginning of the event log, are returned, up to the size of the error buffer to which extracted errors are copied. If the remote computer repeatedly accesses errors, then the remote computer must compare any newly reported errors against all previously reported errors in order to detect duplicative error reports. Finally, the remote computer has no way to access types of events stored in the event log of the SND other than error events.

The member function “getErrors” for class “getErrors2,” provided above on lines 70-88, represents a possible improvement in current error reporting methods represented in the previously discussed implementation of member function “getErrors” for class “getErrors1.” In this improved getErrors, a third calling argument, reference argument “offset,” has been added. The improved implementation is quite similar to the previous implementation, with the exception that the improved implementation begins scanning the entry log at an offset from the beginning of the entry log supplied in reference argument “offset.” In addition, when either the supplied buffer has been filled, or the entry log has been exhausted, the offset from which a subsequent scan of the entry log for errors is returned in the reference argument “offset” to the calling entity. Thus, a remote computer, by storing the offset returned from the improved implementation, may repeatedly call the improved implementation to retrieve errors without receiving duplicate error reports. In other words, for a single remote computer accessing the error reporting capabilities of an SND employing the improved implementation, the problem of duplicate reporting of errors can be eliminated.

The improved implementation, however, does not address reporting events other than errors and does not offer solutions to the previously noted deficiencies in the case of access of the error reporting mechanism by more than one remote computer. For example, a first remote computer may access the error reporting mechanism and retrieve the first ten errors, storing the returned offset in order to prevent retrieval of those same ten errors in a subsequent access. However, a second remote computer, without knowing the offset stored by the first remote computer, will inevitably retrieve the same errors retrieved by the first computer. Unless all remote computers communicate with one another to constantly update a shared offset, duplicative reporting of errors cannot be avoided. However, such coordination among a number of remote computers is not trivial. Furthermore, an event logging and reporting mechanism within an SND must handle event log overflow conditions. Because the EEPROM component cannot provide RAM memory, and must be erased in its entirely in order to remove any entry, an event logging and reporting mechanism is somewhat constrained in its ability to handle event log overflow. One possible approach is to discard all current log events, and restart logging from the beginning of the event log. A second approach is to copy selected events from the event log to a smaller, temporary storage area, flush the event log, and then copy the selected events back to the event log starting at the beginning of the event log. In either case, any offsets returned by errors prior to flushing of the event log are invalid following flushing of the event log. Because the remote computers have no way of knowing when event log overflow conditions occur, they have no way of determining whether or not a returned offset is valid. Use of an invalid offset may result in either duplicative reporting of errors or a failure to report certain logged errors.

Member function “getErrors” for class “getErrors3,” provided above on lines 95-121, presents a second improved error reporting technique. In this second improved implementation, the entire event log is scanned in the while-loop comprising lines 102-114. While there is space in the supplied buffer “buff,” errors found in the scan of the event log are copied to the buffer. Any errors found in the scan of the event log that cannot be copied to the buffer, because the buffer is filled, are instead copied into RAM memory, represented in this implementation by the event array “e,” declared on line 97. Once the scan is completed, the memory component is flushed on line 115 and, in the for-loop comprising lines 116-119, any temporarily stored errors are rewritten to the memory component. This technique guarantees that no error is reported more than once. However, it has the side effect of flushing non-error events, whether or not they have been accessed. Moreover, in certain cases, it may be desirable for more than one remote computer to receive a report of a given error, but an event logging and reporting mechanism within the SND that employs the second improved implementation can never provide a given reported error to more than one remote computer.

A third improved implementation is provided in the member function “getErrors” for class “getErrors4” on lines 128-146, above. In this third improved implementation, an array of Boolean values, “retrieve,” is employed, in correspondence with the event log, to mark events as having been reported or not. Then, in the while-loop of lines 134 and 144, only unreported errors are reported. However, according to this technique, two different remote computers can never receive reports of a particular error, a problem noted with respect to the previous improved implementation. Furthermore, it can be desirable for more than one remote computer to receive the entire list of errors stored in an event log. As one example, a first remote computer can retrieve a list of errors, and may itself crash or otherwise become inaccessible. Those retrieved errors, under the third improved implementation, become irretrievable. A second remote computer cannot therefore take the place of the inaccessible first remote computer in order to analyze the irretrievable errors. An additional problem is that the Boolean array “retrieved” must be stored in non-volatile memory, requiring that the basic memory component in an SND be expanded or reformatted, with corresponding major changes to the firmware or hardware circuits that access the memory component to implement the error logging and reporting mechanism.

The method and system of the present invention involve use of a new type of event, or event log entry, that can be added to an event log to partition the event log into many different classes of reported and unreported events. The new type of event is referred to as a “watermark.”

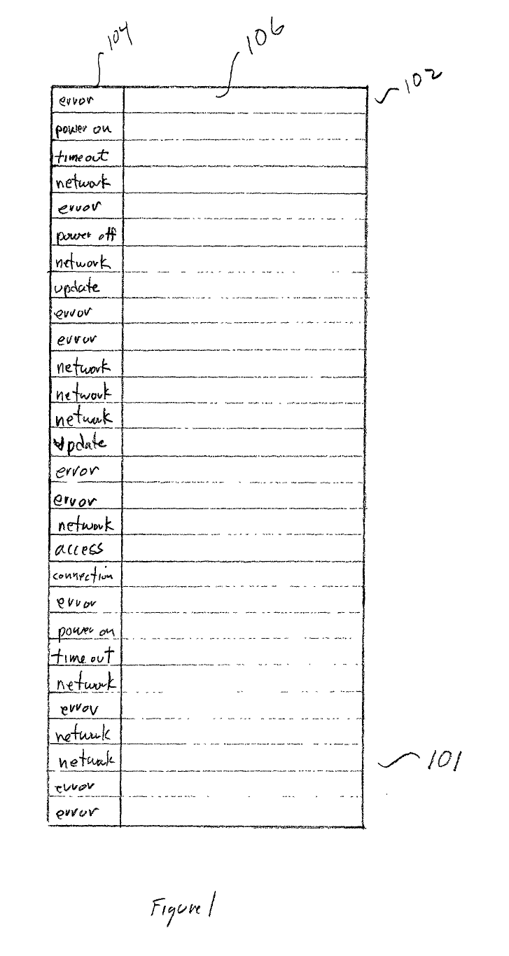

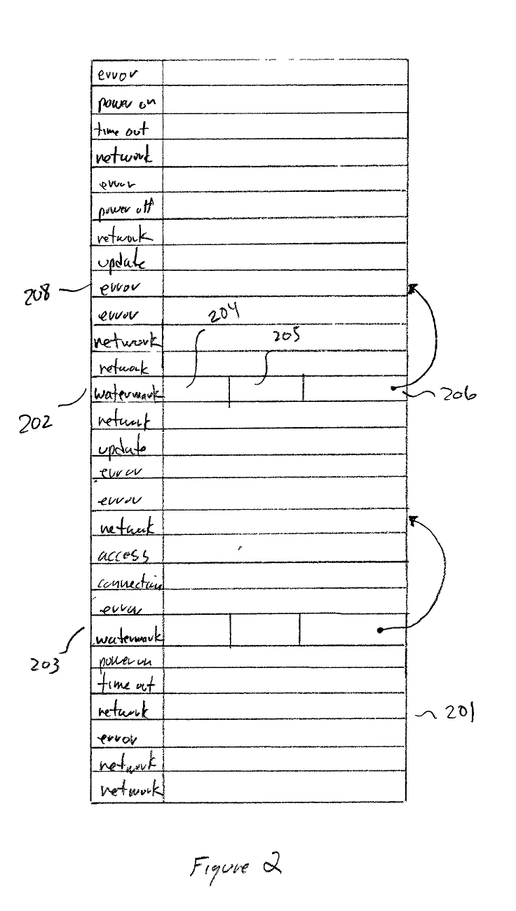

FIG. 2 illustrates an event log that includes watermarks. The event log 201 in FIG. 2 is nearly identical to the event log shown in FIG. 1, with the exception that two watermark events 202 and 203 reside within the event log. A watermark event, such as watermark event 202, may include a number of different informational fields, such as informational fields 204 and 205, and includes an offset field 206 that contains a relative offset from the watermark event to another event within the error log. For example, the offset field 206 of watermark 202 essentially references the error event 208. Watermark events can be thought of as internal placeholders, and are entered into the event log by the same mechanism by which other type of event is entered into the event log. Therefore, use of watermarks does not entail changes to the structure of the event log or implementation of the event log, but only relatively minor changes to firmware or hardware circuitry that implements event logging and reporting within an SND. Watermark events are not generally reportable, but are used by, and visible to, only the event logging and reporting mechanism within an SND that implements an embodiment of the present invention.

The method and system of the present invention can now be illustrated with two additional class declarations and a number of member function implementations:

| | |
|---|---|
| 1 | class watermark : public event |
| 2 | { |
| 3 | |
| 4 | public: |

| | | |
|---|---|---|
| 5 | int | getEntryOffset() {return int1;}; |
| 6 | void | setEntryOffset(int offset) {int1 = offset;}; |
| 7 | eventType | getClass() {return evt1;}; |
| 8 | void | setClass(eventType classType) {evt1 = |

classType;};

| | | |
|---|---|---|
| 9 | int | getRequestorID() {return int2;}; |
| 10 | void | setRequestorID(int id) {int2 = id;}; |

| | |
|---|---|
| 11 | watermark& operator=(watermark&); |
| 12 | watermark(); |
| 13 | watermark(watermark&); |
| 14 | ˜watermark(); |

| | |
|---|---|
| 15 | }; |
| 16 | |
| 17 | watermark& watermark::operator=(watermark& w) |
| 18 | { |

| | |
|---|---|
| 19 | if (this != &w) |
| 20 | { |

| | |
|---|---|
| 21 | this->setIdentifier(w.getIdentifier()); |
| 22 | this->setClass(w.getClass()); |
| 23 | this->setEntryOffset(w.getEntryOffset()); |
| 24 | this->setRequestorID(w.getRequestorID()); |
| 25 | this->setTime(w.getTime()); |

| | |
|---|---|
| 26 | } |
| 27 | return *this; |

| | |
|---|---|
| 28 | } |
| 29 | |
| 30 | watermark::watermark() |
| 31 | { |

| | |
|---|---|
| 32 | this->setIdentifier(Watermark); |

| | |
|---|---|
| 33 | } |
| 34 | |
| 35 | |
| 36 | watermark::watermark(watermark& w) |
| 37 | { |

| | |
|---|---|
| 38 | this->setIdentifier(w.getIdentifier()); |
| 39 | this->setClass(w.getClass()); |
| 40 | this->setEntryOffset(w.getEntryOffset()); |
| 41 | this->setRequestorID(w.getRequestorID()); |
| 42 | this->setTime(w.getTime()); |

| | |
|---|---|
| 43 | } |
| 44 | |
| 45 | class getEvents1 |
| 46 | { |
| 47 | private: |

| | |
|---|---|
| 48 | bareMemory* mem; |

| | |
|---|---|
| 49 | public: |

| | |
|---|---|
| 50 | int getEvents(eventType classE, int requestor, |

| | |
|---|---|
| 51 | eventBuffer buf, int size); |

| | |
|---|---|
| 52 | getEvents1(bareMemory* m); |
| 53 | virtual ˜getEvents1(); |
| 54 | |

| | |
|---|---|
| 55 | }; |
| 56 | |
| 57 | int getEvents1::getEvents(eventType classE, int requestor, |

| | |
|---|---|
| 58 | eventBuffer buf, int size) |

| | |
|---|---|
| 59 | { |

| 60 | event e; | |
|---|---|---|
| 61 | watermark w; | |
| 62 | watermark* water = | reinterpret_cast<watermark*>(&e) |
| 63 | int i = | mem->getNextOffset(); |
| 64 | int j = 0; | |
| 65 | int k = 0; | |
| 66 | | |

| | |
|---|---|
| 67 | if (classE == Watermark) return 0; |
| 68 | if (i > 0) |
| 69 | { |

| | |
|---|---|
| 70 | while (mem->getEntry(--i, e)) |
| 71 | { |

| | |
|---|---|
| 72 | if (e.getIdentifier() == Watermark) |
| 73 | { |

| | |
|---|---|
| 74 | if (water->getClass() == classE && |
| 75 | water->getRequestorID() == requestor) |
| 76 | { |

| | |
|---|---|
| 77 | k = i − water->getEntryOffset(); |
| 78 | if (k < 0) k = 0; |
| 79 | break; |

| | |
|---|---|
| 80 | } |

| | |
|---|---|
| 81 | } |

| | |
|---|---|
| 82 | } |
| 83 | while (mem->getEntry(k, e)) |
| 84 | { |

| | |
|---|---|
| 85 | if (e.getIdentifier() == classE) |
| 86 | { |

| | |
|---|---|
| 87 | *buf++ = e; |
| 88 | j++; |
| 89 | k++; |
| 90 | if (j == size) break; |

| | |
|---|---|
| 91 | } |
| 92 | else k++; |

| | |
|---|---|
| 93 | } |
| 94 | w.setRequestorID(requestor); |
| 95 | w.setClass(classE); |
| 96 | w.setEntryOffset(mem->getNextOffset() − k); |
| 97 | mem->addEntry(&w); |

| | |
|---|---|
| 98 | } |
| 99 | return j; |

| | |
|---|---|
| 100 | } |
| 101 | |
| 102 | getEvents1::getEvents1(bareMemory* m) |
| 103 | { |

| | |
|---|---|
| 104 | mem = m; |

| | |
|---|---|
| 105 | } |

The class “watermark,” declared above on lines 1-15, is derived from the base class “event,” discussed earlier. A watermark event includes additional member functions, declared above on lines 5-10, to store and retrieve an offset, a class of event, and a requester ID. The offset corresponds to the offset field 206 of watermark 202 in FIG. 2. It is a relative offset from the watermark to some other event within the event log. An event class indicates a type of event to which the watermark is related. For example, a watermark, in the current pseudocode implementation, may be related to error events or may be related to other events. The requester ID identifies a particular remote computer with which the watermark is associated. An assignment operator, constructor, and copy constructor for the class “watermark” are implemented on lines 17-43, above. These implementations are straightforward, and are not discussed further.

The class “getEvents1” is declared above on lines 45-55. This class is similar to the four getErrorsX classes, discussed above, except that the class “getEvents1,” an embodiment of the present invention, can report events of any type, and not only error events, as reported by the above described getErrors functions. The class “getEvents1,” representing an event reporting mechanism within an SND employing the present invention, provides a single operation represented by the member function “getEvents,” declared above on lines 50-51. This member function receives four arguments: (1) “classE,” an indication of the type of event to be reported; (2) “requester,” an integer value representing the identity of the remote computer or other entity requesting reporting of events; (3) “buff,” an event buffer into which reported events are copied by getEvents; and (4) “size,” the number of entries that can be placed into the event buffer “buff.” Thus, the member function “getEvents” is similar, in form, to the previously discussed member functions “getErrors,” but includes two additional arguments: one that allows the type of event to be reported to be specified and one that identifies the entity calling the member function “getEvents.”

An implementation of the member function “getEvents” is provided on lines 57-100, above. On line 63, the variable “i” is set to the offset of the first empty entry within the entry log. If the value of i is greater than zero, as detected on line 68, indicating that there are events logged in the event log, then event reporting is undertaken starting on line 70. First, in the while-loop of lines 70-82, the event log is scanned in reverse starting from the last valid entry in the event log. If, during this scan, a watermark event is detected, on line 72 above, if the class stored in the watermark event is equal to the class specified by the calling argument “classE,” and if the requester ID stored in the watermark event is identical to the requester ID specified in calling argument “requester,” as detected on lines 74-75, then the watermark event found during the reverse scan of the event log is related to the request for event reporting represented by the current call to getEvents. In this case, the offset within the watermark event is subtracted from the current position of the scan of the event log, on line 77 above, to produce an absolute offset “k” from the start of the event log of the first entry in the event log from which a forward scan for events should proceed. If no relevant watermark is found in the reverse scan, then, at the conclusion of the while-loop of lines 70-82, k has the value zero. In the second while-loop of lines 83-93, a forward scan of the event log, starting at absolute offset k, is undertaken. During this scan, if an event is found that has an event type identical to the event type specified in the calling argument “classE,” as detected on line 85, then that event is copied into the event buffer provided by calling argument “buff.” If copying of the event to the event buffer completely fills the event buffer “buff,” as detected on line 90, then the forward scan is interrupted. Once the forward scan is completed, getEvents places a watermark in the next available position, or entry, within the event log. The requester ID and class of the watermark are set to the requester ID and class specified in calling arguments “requester” and “classE,” respectively, on lines 94-95. The offset value of the watermark is set relative to the watermark to point to the next entry in the event log to be scanned, in the case that the forward scan was interrupted on line 90 due to filling of the event buffer “buff,” or to the new watermark entry itself, in the case that the event log was completely scanned in the while-loop of lines 83-93. In an alternative embodiment, the offset may have negative values, allowing the offset to reference the next entry in the event log following the watermark in the case that the event log was completely scanned in the while-loop of lines 83-93. On line 99, getEvents returns the number of events of class “classE” copied to the event buffer “buff.”

The present invention, as embodied in getEvents, represents a far more robust and flexible technique for reporting events stored in an event log within an SND. First, the requesting entity, normally a remote computer, can specify the type of event that the requesting entity wishes to receive. Thus, rather than only being able to access error events, the requesting entity can access events of any type. In an alternate implementation, an additional event type value may be defined to represent all events, or numerous additional event type values may be introduced to represent various sets of events, and a requesting entity may use these additional event types to request reporting of various classes of events, or of all events. A second advantage of the technique of the present invention is that each requesting entity can obtain non-duplicative reporting of any type of event from the event reporting mechanism. Additionally, should a number of cooperating remote computers wish to partition affected by each remote computer accessing the event reporting mechanism of the SND to exclusively retrieve one or a number of classes of events. In other words, event reporting can be partitioned among remote computers on the basis of the type of events analyzed and reported by each remote computer. An additional advantage of the present invention is that each remote computer can obtain non-duplicative reporting of any type of error with a guarantee that no errors will be omitted from the report unless the errors have been actually discarded from the memory component by the event reporting mechanism within an SND. Because the offsets stored in watermarks are relative offsets with respect to the location in memory of a containing watermark, watermarks may be relocated within the memory component as long as the order of events within the memory component is not altered during handling of memory component overflow.

Thus, in summary, the technique of the present invention involves entering watermark events into an event log by an event reporting mechanism within an SND. These watermarks indicate a position to resume searching an event log for events of a particular class to report to a particular requesting entity. Watermarks allow the event reporting mechanism within an SND to keep track of ongoing error reporting to a number of different requesting entities, with each entity able to concurrently maintain separate threads of reporting of events for different classes and different types of events.

Although the present invention has been described in terms of a particular embodiment, it is not intended that the invention be limited to this embodiment. Modifications within the spirit of the invention will be apparent to those skilled in the art. For example, a number of different types of fields may be included within a watermark to control partitioning of events in an event log into separate categories for the purpose of event reporting. For example, as discussed, above, various class and subclass fields may be stored in each watermark to partition events to whatever granularity is desirable. As another example, an additional stored identifier field may be introduced so that a particular remote computer can undertake concurrent reporting of the same class of events in a number of different reporting threads identified by the value of the additional field. As still another example, multiple fields may be employed within a watermark to specify ranges of entries within an event log from which events should be collected for reporting. As discussed above, the event class field in the disclosed embodiment allows partitioning of reporting events based on an event type among a number of remote computers. If it is desirable, for a number of remote computers, that each event be reported to only one of the number of remote computers, or, in other words, that no duplicative reporting of events among the number of remote computers should occur, then the number of remote computers may all employ an identical requester ID. The watermark-based technique of the present invention provides increased control, flexibility, and robustness of event reporting by the event reporting mechanism of an SND. An almost limitless number of specific partitioning of events can be reported using this watermark technique. Although the above-described embodiment employs reverse-direction searching for a related watermark, followed by forward-direction searching for events to report, many other types of searching techniques and event reporting strategies and paradigms may be employed, in conjunction with watermarks, to partition logged events and to report logged events. Rather than a relative offset field, a watermark may alternatively contain an absolute offset referencing the next point at which to resume reporting events, or another type of value specifying a search resumption point or search starting point, such as a memory address. In the above-described embodiment, searching for events to report is generally conducted from least recently logged events to most recently logged events, but searching may also be conducted in the reverse direction, or may be conducted in some other pattern around a logged event, including a watermark, so as to find events of interest to a particular host computer.

The foregoing description, for purposes of explanation, used specific nomenclature to provide a thorough understanding of the invention. However, it will be apparent to one skilled in the art that the specific details are not required in order to practice the invention. In other instances, well-known circuits and devices are shown in block diagram form in order to avoid unnecessary distraction from the underlying invention. Thus, the foregoing descriptions of specific embodiments of the present invention are presented for purposes of illustration and description; they are not intended to be exhaustive or to limit the invention to the precise forms disclosed, obviously many modifications and variations are possible in view of the above teachings. The embodiments were chosen and described in order to best explain the principles of the invention and its practical applications and to thereby enable others skilled in the art to best utilize the invention and various embodiments with various modifications as are suited to the particular use contemplated. It is intended that the scope of the invention be defined by the following claims and their equivalents:

1. A method for reporting events stored in an event log within an electronic device, the method comprising:
receiving a request for a report of events of a specified type from a specified requester;
searching for a watermark event related to the specified event type and specified requestor;
when a related watermark event is found, using a value stored within the watermark to select an event at which to begin searching the event log for events of the specified type to report to the specified requester;
when a related watermark event is not found, selecting a default event at which to begin searching the event log for events of the specified type to report to the specified requester; and
searching the event log starting at the selected event to find and report events of the specified type.

2. The method of claim 1 wherein searching for a watermark event related to the specified event type and specified requestor further includes:
selecting an event most recently logged in the event log as a first event;
starting with the selected first event and preceding sequentially towards the least recently logged event, sequentially selecting each event as a candidate event;
when the selected candidate event is a watermark event with an event type field containing an indication of the specified event type and a requester field containing an indication of the specified requester, returning the selected candidate watermark event as a positive search result; and
when the least recently logged event has been selected, and is not a watermark event with an event type field containing an indication of the specified event type and a requestor field containing an indication of the specified requestor, returning a negative search result.

3. The method of claim 1 wherein the value stored within the watermark used to select an event at which to begin searching the event log for events of the specified type to report to the specified requester is a relative offset from the watermark to the selected event at which to begin searching the event log.

4. The method of claim 1 wherein the value stored within the watermark used to select an event at which to begin searching the event log for events of the specified type to report to the specified requester is an offset from a logged event within the event log to the selected event at which to begin searching the event log.

5. The method of claim 1 wherein the value stored within the watermark used to select an event at which to begin searching the event log for events of the specified type to report to the specified requester is an address of the selected event.

6. The method of claim 1 wherein the default event at which to begin searching the event log for events is the first event in the event log.

7. The method of claim 1 wherein searching the event log at the selected event to find and report events of the specified type further includes examining each event in the event log, starting at the selected event, until either a specified number of events of the specified type are found or until all events in the event log between and including the selected event and a final event have been examined.

8. The method of claim 7 wherein the final event is most recently logged event in the event log.

9. The method of claim 7 wherein the final event is the least recently logged event in the event log.

10. The method of claim 1 wherein, following searching the event log starting at the selected event to find and report events of the specified type, a new watermark event including indications of the specified event type and specified requestor is inserted into the event log.

11. The method of claim 10 wherein the new watermark includes a relative offset to a next event in the event log following a last event reported.

12. The method of claim 10 wherein the new watermark includes a relative offset to a next position in the event log following the new watermark.

13. The method of claim 10 wherein the new watermark includes a relative offset of 0.

14. An event reporting system within an electronic device, the event reporting system comprising:
a non-volatile memory component;
an event log stored within the memory component that sequentially stores events; and
event reporting logic that stores a watermark event to note the extent of a first search for events to report to a specified event report requestor and that subsequently accesses the stored watermark event to identify a location within the event log to begin a second search for events to report to the specified event report requestor.

15. The event reporting system of claim 14 wherein the non-volatile memory component is selected from among a flash memory and an electronic erasable programmable read-only memory.

16. The event reporting system of claim 14 wherein the event log is a table of entries, each entry representing a single logged event and containing a field that identifies the type of event represented by the entry.

17. The event reporting system of claim 14 wherein a watermark event entry includes fields identifying the event represented by the entry as a watermark event and additional fields indicating a type of event to which the watermark is directed and an identifier of an event report requestor associated with the watermark.

18. The event reporting system of claim 14 wherein a watermark event includes a field containing a relative offset from the watermark entry to the location within the event log to begin a second search for events to report.

19. The event reporting system of claim 14 wherein a watermark event includes a field containing an absolute offset from an entry in the event log to the location within the event log to begin a second search for events to report.

20. The event reporting system of claim 14 wherein a watermark event includes a field containing an address of the location within the event log to begin a second search for events to report.
